(19) United States
(12) Patent Application Publication
(10) Pub. No.: US 2005/0279285 A1
(43) Pub. Date: Dec. 22, 2005

(54) Phosphor sheet manufacturing apparatus

(75) Inventors: Makoto Kashiwaya, Kanagawa (JP); Junji Nakada, Shizuoka (JP); Yukihisa Noguchi, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: FUJI PHOTO FILM CO., LTD.

(21) Appl. No.: 11/149,424

(22) Filed: Jun. 10, 2005

(30) Foreign Application Priority Data
Jun. 10, 2004 (JP) 2004-172708
Jun. 10, 2004 (JP) 2004-172868

(51) Int. Cl. C23C 16/00

(52) U.S. Cl. 118/726; 118/719

(57) ABSTRACT

There is provided a stimulable phosphor sheet manufacturing apparatus which forms a stimulable phosphor layer through vacuum evaporation in a vacuum chamber. A substrate is conveyed linearly, evaporation sources are arranged in a direction perpendicular to a direction in which the substrate is conveyed, and/or the apparatus includes the evaporation sources relying on resistance heating and a gas introducing nozzle for introducing an inert gas into a vacuum chamber during film formation. A phosphor layer of highly uniform film thickness distribution can be formed.

This application claims priority on Japanese patent applications No.2004-172708 and No. 2004-172868, the entire contents of which are hereby incorporated by reference. In addition, the entire contents of literatures cited in this specification are incorporated by reference. In addition, the entire contents of literatures cited in this specification are incorporated by reference.

### BACKGROUND OF THE INVENTION

The present invention relates to an apparatus for manufacturing a stimulable phosphor sheet for use in radiation image recording (photographing) in computed radiography (CR) or the like. More specifically, the present invention relates to a phosphor sheet manufacturing apparatus that forms a layer made of a stimulable phosphor on the surface of a substrate by vacuum evaporation.

There are known a class of phosphors which accumulate a portion of applied radiations (e.g. x-rays, α-rays, β-rays, γ-rays, electron beams, and uv (ultraviolet) radiation) and which, upon stimulation by exciting light such as visible light, give off a burst of light emission in proportion to the accumulated energy. Such phosphors called stimulable phosphors are employed in medical and various other applications.

An exemplary application is a radiation image information recording and reproducing system which employs a phosphor sheet having a phosphor layer formed of the stimulable phosphor. The sheet is also hereunder referred to as a radiation image converting sheet. This radiation image information recording and reproducing system has already been commercialized as FCR (Fuji Computed Radiography).

In that system, radiation image information about the subject such as the human body is recorded on the phosphor sheet (more specifically, the phosphor layer). After the radiation image information is thus recorded, the phosphor sheet is irradiated with exciting light to produce photostimulated luminescence which, in turn, is read photoelectrically to yield an image signal. Then, an image reproduced on the basis of the read image signal is output as the radiation image of the subject, typically to a display device such as CRT or on a recording material such as a photographic material.

The phosphor sheet is typically produced by the steps of first preparing a coating solution having the particles of a stimulable phosphor dispersed in a solvent containing a binder, etc., applying the coating solution to a support in sheet form that is made of glass or resin, and drying the applied coating.

Phosphor sheets are also known that are made by forming a phosphor layer on a support through methods of physical vapor deposition (vapor-phase film formation) such as vacuum evaporation, as disclosed in JP 2789194 B and JP 5-249299 A. The phosphor layer prepared by evaporation has excellent characteristics. First, it contains less impurities since it is formed under vacuum; in addition, it is substantially free of any substances other than the stimulable phosphor, as exemplified by the binder, so it has high uniformity in performance and still assures very high luminous efficiency.

Incidentally, as a method of reading a phosphor sheet having a radiation image taken thereon, there is known a method that employs a linear light source and a line sensor extending in the same direction as the direction in which the light source extends. In this method, the light source and the line sensor are moved in synchronism in a direction perpendicular to the direction in which the two components extend, whereby photostimulated luminescence is read by the line sensor while the light source irradiates the phosphor sheet with exciting light.

To effect suitable image reading when performing phosphor sheet reading using such a line sensor, it is necessary to maintain a proper gap between the surface of the phosphor sheet (phosphor layer) and the line sensor (light receiving surface). For that purpose, it is necessary for the thickness of the phosphor layer to be uniform.

That is, when the photostimulated luminescence is not focused on the line sensor, a problem occurs, such as blurring of the read image. In particular, for medical use as in the case of the FCR mentioned above, such deterioration in image quality may lead to a serious problem, such as a discrepancy in diagnosis result or a wrong diagnosis. Thus, in order to properly read a radiation image taken on a phosphor sheet, it is necessary to properly focus the photostimulated luminescence generated by the phosphor sheet on the line sensor (the light receiving surface thereof).

Naturally, to properly focus photostimulated luminescence on the line sensor, it is necessary to maintain a proper gap between the phosphor sheet and the line sensor. The gap between the line sensor and the phosphor sheet is usually approximately 100 μm. On the other hand, in a phosphor sheet having a phosphor layer formed by evaporation, the thickness of the phosphor layer is usually approximately 500 μm, and in some cases exceeds 1000 μm. Thus, when the size of the gap between them is taken into account, the film thickness distribution of the phosphor sheet constitutes a great error factor for the gap between the line sensor and the phosphor sheet.

An examination conducted by the present inventors shows that, in order to read a high quality radiation image by properly focusing photostimulated luminescence from the phosphor sheet on the line sensor, it is desirable for the film thickness distribution of the phosphor layer to be ±3% or less (for example, ±18 μm or less when the film thickness is 600 μm). In particular, it is desirable for the film thickness distribution to be ±2% or less.

As a method of solving the above problem, a method as disclosed, for example, in JP 2003-344591 A, is available. According to the method disclosed in the above publication, in a phosphor sheet manufacturing apparatus for forming a phosphor layer by vacuum evaporation, a reduction in phosphor layer thickness distribution is achieved by forming a phosphor layer while rotating a substrate at a rate of 500 RPM or more.

While it helps achieve a reduction in film thickness distribution of a phosphor layer formed by vacuum evaporation, this method requires a high-speed substrate rotating means, resulting in a rather high apparatus cost. Further, since the substrate is rotated at high speed, it is necessary to perform maintenance frequently, resulting in a rather high running cost.

Further, in making the thickness of a film formed by vacuum evaporation uniform, the position of an evaporation source (a heating/evaporating unit for the film forming material, that is, the crucible) is important. However, in the vacuum evaporation conducted while rotating the substrate, the setting of the position of the evaporation source is very difficult to perform. In particular, when resistance heating is adopted, even a slight inadequacy in the position setting of the evaporation source may lead to the case where a phosphor layer whose uniformity in film thickness distribution is ±3% or less cannot be formed in a consistent manner.

### SUMMARY OF THE INVENTION

The present invention has been made to solve the problems inherent in the prior art, and an object of the present invention is to provide a phosphor sheet manufacturing apparatus which forms a phosphor layer by vacuum evaporation, which ensures high uniformity in film thickness distribution without rotating a substrate at high speed or performing high-accuracy position setting of an evaporation source and which is capable of forming a phosphor layer having excellent crystallinity.

In order to achieve the object, according to a first aspect of the present invention, there is provided a phosphor sheet manufacturing apparatus for forming a stimulable phosphor layer on a surface of a sheet-like substrate through vacuum evaporation, including: a vacuum chamber in which said vacuum evaporation is performed; vacuum evacuating means for evacuating said vacuum chamber; substrate conveying means for conveying said substrate along a linear conveyance route in said vacuum chamber; and evaporation sources accommodated in said vacuum chamber, arranged below said linear conveyance route along which said substrate is conveyed by said substrate conveying means, and arrayed in a first direction perpendicular to a second direction in which said substrate is conveyed.

In the phosphor sheet manufacturing apparatus according to the first aspect of the present invention, it is preferable that said stimulable phosphor layer is formed while said substrate is conveyed in a to-and-fro manner by said substrate conveying means. Further, it is preferable that said vacuum evaporation is multi-source vacuum evaporation through which said stimulable phosphor layer is formed using film forming materials, and wherein evaporation sources for each film forming material in said film forming materials are arranged in said first direction perpendicular to said second direction to make a row of evaporation sources, and rows of evaporation sources for respective film forming materials are arrayed in said second direction in which said substrate is conveyed. Further, it is preferable that evaporation sources for said one film forming material and their corresponding evaporation sources for another film forming material are arranged side by side in said second direction in which said substrate is conveyed. Further, it is preferable that said film forming materials include a first film forming material constituting a phosphor component and a second film forming material constituting an activator component, and wherein first evaporation sources for said first film forming material are paired with second evaporation sources for said second film forming material and pairs of said first and second evaporation sources are arranged side by side in said second direction in which said substrate is conveyed. Further, it is preferable that said evaporation sources have slit-like vapor discharge ports, and wherein said evaporation sources are arranged such that a longitudinal direction of each of said slit-like vapor discharge ports is matched with said first direction perpendicular to said second direction. Further, it is preferable that at least one of said film forming materials is capable of controlling its evaporation for each evaporation source. Further, it is preferable that evaporation sources for each of said film forming materials are provided in rows and said evaporation sources in the rows are arranged such that, when seen in said second direction in which said substrate is conveyed, vapor discharge ports of adjacent rows are arranged alternately. Further, it is preferable that a row of evaporation sources for one film forming material whose evaporation amount is largest in said film forming materials is arranged outermost in said second direction in which said substrate is conveyed. Further, it is preferable that said evaporation sources heat film forming materials by resistance heating or induction heating. Further, it is preferable to include gas introducing means which introduces an inert gas into said vacuum chamber during film formation to adjust a degree of vacuum in said vacuum chamber. Further, it is preferable that said stimulable phosphor layer is formed by adjusting an internal pressure of said vacuum chamber to from 0.1 to 10 Pa through introduction of said inert gas by said gas introducing means. Further, it is preferable that said substrate conveying means comprises: guide means extending in said second direction in which said substrate is conveyed; substrate retaining means having engagement portions which are engaged with said guide means; driving means for moving said substrate retaining means in said second direction in which said substrate is conveyed; and a heat insulating mechanism for preventing said engagement portions from being heated by radiation heat from said evaporation sources. Furthermore, it is preferable that said stimulable phosphor layer is made of a stimulable phosphor that is expressed by a general formula: “CsBr:Eu”.

Further, according to a second aspect of the present invention, there is phosphor sheet manufacturing apparatus for forming a stimulable phosphor layer on a surface of a sheet-like substrate through vacuum evaporation, including: a vacuum chamber in which said vacuum evaporation is performed; vacuum evacuating means for evacuating said vacuum chamber; resistance heating means for heating film forming materials of said stimulable phosphor layer by resistance heating, said resistance heating means being accommodated in said vacuum chamber; substrate conveying means for conveying said substrate along a linear conveyance route above said resistance heating means in said vacuum chamber; and gas introducing means for introducing an inert gas into said vacuum chamber during film formation of said stimulable phosphor layer to adjust a degree of vacuum in said vacuum chamber.

In the phosphor sheet manufacturing apparatus according to the second aspect of the present invention, it is preferable that said substrate conveying means comprises: guide means extending in a direction in which said substrate is conveyed along said linear conveyance route; substrate retaining means having engagement portions which are engaged with said guide means; driving means for moving said substrate retaining means in said direction in which said substrate is conveyed; and a heat insulating mechanism for preventing said engagement portions from being heated by radiation heat from said resistance heating means. Further, it is preferable that said stimulable phosphor layer is formed by adjusting an internal pressure of said vacuum chamber to from 0.1 to 10 Pa through introduction of said inert gas by said gas introducing means. Further, it is preferable that said stimulable phosphor layer is formed while said substrate conveying means conveys said substrate in a to-and-fro manner along said linear conveyance route. Furthermore, it is preferable that said stimulable phosphor layer is made of a stimulable phosphor that is expressed by a general formula: “CsBr:Eu”.

In the phosphor sheet manufacturing apparatus according to the first aspect of the present invention, in manufacturing a phosphor sheet through formation of a phosphor layer (a layer made of a stimulable phosphor) by vacuum evaporation, a substrate is conveyed linearly (preferably repeatedly moved in a to-and-fro manner), and evaporation sources for film forming materials are arranged linearly in a direction perpendicular to the direction in which the substrate is conveyed, thereby forming the phosphor layer. As a result, the entire substrate surface can be exposed to the vapor of the film forming materials with very high uniformity, which makes it possible to manufacture a phosphor sheet exhibiting a very satisfactory film thickness distribution of ±3% or less. Further, it is desirable for the formation of the phosphor layer through vacuum evaporation to be effected by a multi-source vacuum evaporation method in which a phosphor component constituting the base material and an activator component which is a minute-amount component are put in separate evaporation sources. In accordance with the present invention in which the substrate is conveyed linearly and the evaporation sources are arranged in a direction perpendicular to the direction in which the substrate is conveyed, it is possible to disperse the activator component in the phosphor layer with high uniformity in both the planar direction and thickness direction of the phosphor layer. Thus, it is possible to obtain a phosphor sheet superior in photostimulated luminescence characteristics and uniformity in sensitivity, etc.

According to the second aspect of the present invention, there is provided a phosphor sheet manufacturing apparatus which includes means for heating film forming materials by resistance heating and a gas introducing nozzle for introducing an inert gas into a vacuum chamber (film formation system), and in which a phosphor layer is formed through vacuum evaporation while conveying a substrate linearly (preferably while moving the substrate in a to-and-fro manner). Thus, it is possible to form a phosphor layer having excellent crystallinity and exhibiting a highly uniform film thickness distribution of 3% or less, and to facilitate the position setting for the evaporation sources.

### BRIEF DESCRIPTION OF THE DRAWINGS

In the accompanying drawings:

FIG. 1A is a schematic front view of an embodiment of a phosphor sheet manufacturing apparatus according to the present invention;

FIG. 1B is a schematic side view of the phosphor sheet manufacturing apparatus shown in FIG. 1A;

FIG. 2A is a schematic plan view of substrate retaining/conveying means of the phosphor sheet manufacturing apparatus shown in FIGS. 1A and 1B;

FIG. 2B is a schematic front view of the substrate retaining/conveying means of the phosphor sheet manufacturing apparatus shown in FIGS. 1A and 1B;

FIG. 2C is a schematic side view of the substrate retaining/conveying means of the phosphor sheet manufacturing apparatus shown in FIGS. 1A and 1B;

FIG. 3 is a schematic plan view of a heating/evaporating unit of the phosphor sheet manufacturing apparatus shown in FIGS. 1A and 1B;

FIG. 4A is a diagram showing another example of an evaporation source that can be used in the phosphor sheet manufacturing apparatus according to the present invention;

FIG. 4B is a cross-sectional view of the evaporation source shown in FIG. 4A taken along the line b-b; and

FIG. 4C is a diagram showing still another example of the evaporation source that can be used in the phosphor sheet manufacturing apparatus according to the present invention.

### DETAILED DESCRIPTION OF THE INVENTION

The phosphor sheet manufacturing apparatus of the present invention will hereinafter be described in detail on the basis of a preferred embodiment shown in the accompanying drawings.

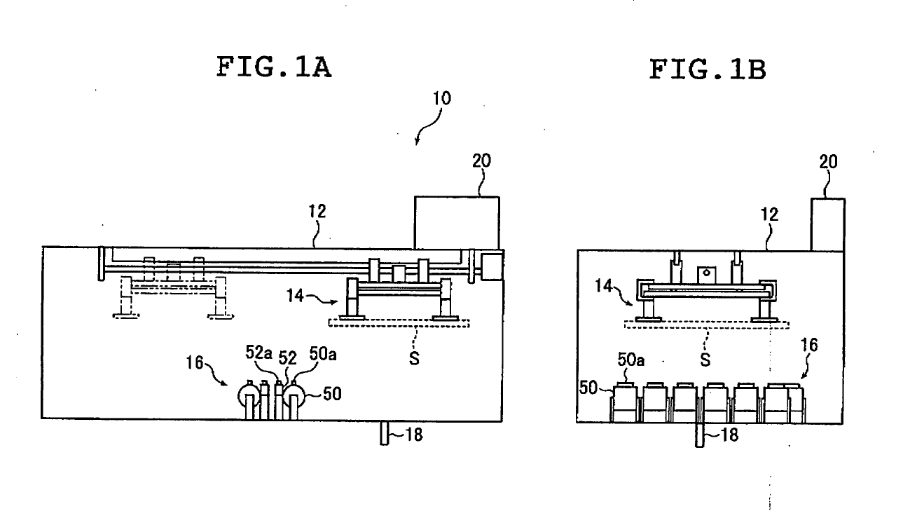

FIGS. 1A and 1B are a front view and a side view conceptually showing an embodiment of the phosphor sheet manufacturing apparatus of the present invention.

The phosphor sheet manufacturing apparatus 10 (hereinafter referred to as the manufacturing apparatus 10) shown in FIGS. 1A and 1B is an apparatus for manufacturing a phosphor sheet by forming on the surface of a substrate S a phosphor layer (a layer consisting of a stimulable phosphor) through two-source vacuum evaporation in which a material constituting the phosphor (base material) and a material constituting the activator are separately evaporated.

The manufacturing apparatus 10 basically includes a vacuum chamber 12, a substrate retaining/conveying mechanism 14, a heating/evaporating unit 16 (quartz oscillator sensors 54 to be described later are not shown), a gas introducing nozzle 18 and an RF matching box 20. It goes without saying that, apart from these components, the manufacturing apparatus 10 of the present invention may include various components with which a well-known vacuum evaporation apparatus is equipped.

The manufacturing apparatus 10 of the present invention is not limited to the two-source vacuum evaporation apparatus in the illustrated case but may be a one-source vacuum evaporation apparatus in which all the film forming materials are mixed and put in an evaporation source to perform one-source vacuum evaporation. Alternatively, the manufacturing apparatus 10 of the present invention may be an apparatus in which three or more kinds of film forming materials are put in different evaporation sources to perform three or more-source vacuum evaporation. A multi-source vacuum evaporation apparatus is preferably used in which film forming materials are put in different evaporation sources to perform two or more-source vacuum evaporation.

In the illustrated case, as a suitable example, a phosphor sheet is prepared by forming a phosphor layer of a stimulable phosphor CsBr:Eu on the substrate S through two-source vacuum evaporation by resistance heating using film forming materials including cesium bromide (CsBr) as the phosphor component and europium bromide (EuBrₓ (where x is generally 2 to 3 and preferably 2)) as the activator component.

The manufacturing apparatus 10 also includes the gas introducing nozzle 18 for introducing an inert gas during the film formation. Preferably, the gas introducing nozzle 18 is used in the manufacturing apparatus 10 to evacuate the vacuum chamber 12 to a high degree of vacuum and then an inert gas is introduced through the gas introducing nozzle 18 while the vacuum chamber 12 is kept evacuated to a degree of vacuum of about 0.1 to 10 Pa (this degree of vacuum is hereinafter referred to as medium vacuum). The film forming materials (cesium bromide and europium bromide) are heated and evaporated under medium vacuum whereby a phosphor layer is formed on the substrate S through vacuum evaporation.

In addition, the film forming materials are heated and evaporated through resistance heating in the heating/evaporating unit 16 and a phosphor layer is formed on the substrate S through vacuum evaporation while the substrate S is linearly conveyed by the substrate retaining/conveying mechanism 14 (this movement is hereinafter referred to as “linear conveyance”).

In the present invention, various materials can be used instead of CsBr:Eu as the stimulable phosphor which is a target for film formation. For example, JP 57-148285 A preferably discloses alkali halide-based stimulable phosphors represented by the general formula “M^{I}X·aM^{II}X′₂·bM^{III}X″₃:cA” In this formula, M^{I} represents at least one element selected from the group consisting of Li, Na, K, Rb, and Cs. M^{II} represents at least one divalent metal selected from the group consisting of Be, Mg, Ca, Sr, Ba, Zn, Cd, Cu, and Ni. M^{III} represents at least one trivalent metal selected from the group consisting of Sc, Y, La, Ce, Pr, Nd, Pm, Sm, Eu, Gd, Tb, Dy, Ho, Er, Tm, Yb, Lu, Al, Ga, and In. X, X′, and X″ each represent at least one element selected from the group consisting of F, Cl, Br, and I. A represents at least one element selected from the group consisting of Eu, Tb, Ce, Tm, Dy, Pr, Ho, Nd, Yb, Er, Gd, Lu, Sm, Y, Tl, Na, Ag, Cu, Bi, and Mg, a satisfies a relationship of 0≦a<0.5, b satisfies a relationship of 0≦b<0.5, and c satisfies a relationship of 0≦c<0.2.

Further, preferable stimulable phosphors other than those described above are disclosed in U.S. Pat. No. 3,859,527, JP 55-012142 A, JP 55-012144 A, JP 55-012145 A, JP 57-148285 A, JP 56-116777 A, JP 58-069281 A, and JP 59-075200 A.

In particular, the alkali halide-based stimulable phosphors are preferred in terms of the photostimulated luminescence characteristics, sharpness of reproduced images, the ability to suitably exhibit the effects of the present invention, and the like. Of those, the alkali halide-based stimulable phosphors in which M^{I} contains at least Cs, X contains at least Br, and A is Eu or Bi are more preferred. Of those, “CsBr:Eu” is particularly preferred.

Further, the substrate S is not particularly limited and all types of substrates used in a phosphor sheet such as glass, ceramics, carbon, aluminum, PET (polyethylene terephthalate), PEN (polyethylene naphthalate), and polyamide are available. There is no particular limitation on the shape of the substrate S.

The substrate S used in the illustrated case has for example a rectangular shape.

The vacuum chamber 12 is a well-known vacuum chamber (bell jar or vacuum vessel) used in a vacuum evaporation apparatus and is formed of iron, stainless steel, aluminum, or the like.

The gas introducing nozzle 18 is also a well-known gas introducing means that has (or is connected to) a means for connecting the nozzle 18 to a gas bomb and a gas flow rate adjusting means and is used in a vacuum evaporation apparatus or a sputtering apparatus. The gas introducing nozzle 18 introduces an inert gas such as argon gas or nitrogen gas into the vacuum chamber 12 in order to form a phosphor layer through vacuum evaporation under medium vacuum.

The RF matching box 20 performs plasma cleaning of the surface of the substrate S prior to the formation of the phosphor layer (vacuum evaporation).

A vacuum pump (not shown) is connected to the vacuum chamber 12.

There are no particular limitations regarding the vacuum pump, and various types of vacuum pumps as used in vacuum evaporation apparatuses can be used as long as they help attain the requisite degree of vacuum. Examples of the vacuum pump that can be used include an oil diffusion pump, a cryogenic pump, and a turbo molecular pump; further, as an auxiliary component, it is also possible to use a cryogenic coil or the like in combination. It is to be noted that in the manufacturing apparatus 10 for forming a phosphor layer, it is desirable for the ultimate degree of vacuum in the vacuum chamber 12 to be 8.0×10⁻⁴ Pa or less.

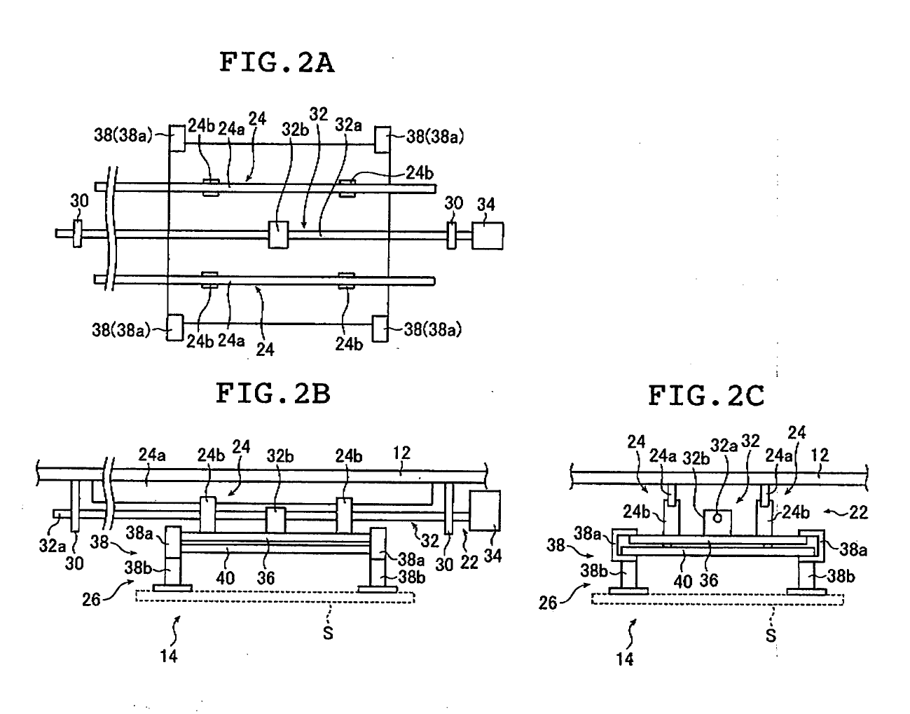

The substrate retaining/conveying mechanism 14 retains the substrate S and conveys it linearly. FIGS. 2A, 2B and 2C are a plan view, a front view and a side view showing an outline of the substrate retaining/conveying mechanism 14. As schematically shown in FIGS. 2A, 2B and 2C, the substrate retaining/conveying mechanism 14 includes driving means 22, linear motor guides 24 and substrate retaining means 26 for retaining the substrate S.

The driving means 22 moves the substrate retaining means 26 (that is, the substrate S) in the direction in which the above-mentioned linear conveyance is effected. The driving means 22 consists of a well-known ball-screw-based linear movement mechanism including a ball screw 32 composed of a screw shaft 32a rotatably supported by retaining members 30 and a nut portion 32b screw together with the screw shaft 32a, and a motor 34 for rotating the screw shaft 32a. The screw shaft 32a extends in the direction in which the substrate S is conveyed (hereinafter referred to as the “conveying direction”; further, the direction perpendicular to the conveying direction will be referred to as the “conveyance perpendicular direction”).

In the present invention, the driving means 22 is not restricted to one which uses the ball screw 32 and the motor 34. As the driving means 22, it is possible to use various well-known linear moving (conveying) means having the requisite heat resistance, such as a conveying means using a cylinder, a conveying means using a motor and a ring-shaped chain rotated by the motor.

The linear motor guide 24 (hereinafter referred to as the LM guide 24) supports the linear conveyance of the substrate retaining means 26 (that is, the substrate S) by the driving means 22. The LM guide 24 is a well-known linear motor guide composed of guide rails 24a and catching members 24b engaged with the guide rails 24a so as to be movable in the longitudinal direction.

Two guide rails 24a extending in the conveying direction are arranged with a gap symmetrically with respect to the screw shaft 32a, with both the guide rails being fixed to the ceiling surface of the vacuum chamber 12. In total four catching members 24b are fixed to the substrate retaining means 26 (the upper surface of a base 36 to be described below), with two of them being engaged with each guide rail 24a.

The substrate retaining means 26 (hereinafter referred to as the retaining means 26) retains the substrate S and is moved linearly by the driving means 22 while being guided by the LM guide 24. The substrate retaining means 26 includes the base 36, a retaining mechanism 38, and a heat insulating member 40.

The base 36 is a rectangular flat member which is horizontal when the manufacturing apparatus 10 is properly installed.

The nut portion 32b of the ball screw 32 is fixed to the center of the upper surface of the base 36; Further, fixed at diagonally symmetrical positions on the upper surface of the base 36 are the catching members 24b of the LM guide 24, which are arranged at a distance determined by the distance between the two guide rails 24a.

The retaining mechanism 38 retains the substrate S at the lower end and includes four mounting members 38a and four retaining members 38b, which are arranged at the four corners of the base 36.

The mounting members 38a are rectangular members with a substantially C-shaped cross section. The mounting members 38a are set from the outer side in the conveyance perpendicular direction, with their C-shaped openings being directed inwards, and part of the ceiling surfaces of their C-shaped portions being placed on the corner portions of the base 36 such that the mounting members 38 are suspended from the base 36. Thus, below the base 36, the retaining means 26 has a space with an area larger than the area of the base 36.

The retaining members 38b have a means for retaining the substrate S provided at the lower ends thereof, and are fixed so as to be suspended from the mounting members 38a. That is, the retaining mechanism 38 for retaining the substrate S is suspended from the base 36 near the corner portions.

In the present invention, there are no particular limitations regarding the way the substrate S is retained by the retaining mechanism 38 (retaining members 38b); various well-known methods of retaining a plate-like object from the upper surface thereof are available, as exemplified by a method using a jig or the like, a method utilizing static electricity, and a method utilizing suction. Further, depending on the area of the substrate S on which the phosphor layer is to be deposited, a retaining means with which the four corners of the substrate S are retained from below or a retaining means with which the four sides of the substrate S are retained from below, may be utilized if possible by means of jigs or the like.

Further, the lower end positions of the retaining members 38b, that is, the height at which the substrate S is retained/conveyed may be made adjustable by a method in which spacers are put between the mounting members 38a and the retaining members 38b, a method using an adjusting means made up of screws, or a method in which ascent/descent means made up of cylinders are provided.

As stated above, the base 36 is linearly conveyed by the driving means 22. Thus, the substrate retaining/conveying mechanism 14 linearly conveys the substrate S by retaining, for example, the vicinities of the four corners of the substrate S by the retaining mechanism 38 and conveying the retaining means 26 by the driving means 22.

As described below, in the present invention, a phosphor layer is formed by conveying the substrate S linearly and arranging evaporation sources in the conveyance perpendicular direction and/or performing medium vacuum evaporation through resistance heating. Herewith the phosphor layer formed is highly uniform in film thickness distribution and further exhibits excellent crystallinity.

In the present invention, as long as a phosphor layer of the requisite film thickness can be formed, the linear conveyance of the substrate S during film formation may be performed through one linear conveyance, one to-and-fro movement (to-and-fro conveyance), or more than one to-and-fro movement. Further, as long as it is generally linear, the substrate may have a more or less zigzag or undulating conveying route.

Generally speaking, the more the number of times the substrate S passes over the heating/evaporating unit 16 is increased, the higher the uniformity of the film thickness distribution can be made. Thus, in the manufacturing apparatus 10, it is desirable to form a phosphor layer by repeatedly moving the substrate S in a to-and-fro manner. The number of times the substrate S is moved in a to-and-fro manner is determined as appropriate based on the desired film thickness of the phosphor layer, the desired uniformity in film thickness distribution, or the like; the last conveyance may be carried out in one direction only. There are no particular limitations regarding the speed at which the linear conveyance is effected; it may be determined as appropriate based on the limit speed of the LM guide 24, the number of times the substrate S is moved in a to-and-fro manner, the desired thickness of the phosphor layer, etc.

In the retaining means 26 retaining the substrate S, directly below the base 36 to the upper surface of which there are fixed the nut portion 32b of the ball screw 32, the catching members 24b of the LM guide 24, etc., there is arranged the heat insulating member 40. As stated above, the manufacturing apparatus 10 in the illustrated embodiment uses the substantially C-shaped mounting members 38a to secure the retaining members 38b in the state in which the member 38b are suspended from the base 36, whereby there is provided below the base 36 a space wider than the base 36. In the illustrated embodiment, the space is utilized to make the area of the heat insulating member 40 larger than the area of the base 36, thereby covering the entire lower surface of the base 36 with the heat insulating member 40 with sufficient margin.

The heat insulating member 40 covers the base 36 against the heating/evaporating unit 16 (evaporation source) to be described below, thereby preventing the catching members 24b of the LM guide 24, the nut portion 32b of the ball screw 32, etc. from being heated by the radiation heat from the heating/evaporating unit 16.

As described below in detail, to manufacture a phosphor sheet which has a superior crystal structure capable of realizing high photostimulated luminescence characteristics and image sharpness and which exhibits superior uniformity in film thickness allowing the reading of radiation images with high accuracy by a line sensor, it is desirable to perform medium vacuum evaporation using resistance heating or the like while conveying the substrate S linearly.

As is well known in the art, balls are incorporated into the catching members 24b of the LM guide 24 and the nut portion 32b of the ball screw 32 to allow them to perform smooth movement. Further, to allow smooth rolling of the balls, a lubricant such as grease is injected into these components. Further, to allow smooth driving without using any balls, a lubricant such as grease is usually injected into the sliding portions of the driving means and the conveyance guide means.

It should be noted however that, in vacuum evaporation using resistance heating, heating is directly effected by energizing crucibles containing film forming materials. Accordingly, as compared with the vacuum evaporation using the electron heating described in JP 2003-344591 A mentioned above or the like, the radiation heat from the evaporation source is very intense. Thus, the catching members 24b and the nut portion 32b are heated by the radiation heat, which may cause various problems, such as defective operation due to grease outflow.

Further, as described in detail below, in medium vacuum evaporation, it is necessary to arrange the substrate S and the evaporation source close to each other. As a result, the evaporation source is arranged very close to the catching members 24b and the nut portion 32b. Thus, it is very likely that the catching members 24b and the nut portion 32b are heated.

That is, while it allows formation of a phosphor layer superior in characteristics and uniformity in film thickness, medium vacuum evaporation in which the substrate is linearly conveyed is likely to involve generation of a defective operation due to grease outflow from the catching members 24b and the nut portion 32b. Thus, an apparatus in which this vacuum evaporation is conducted involves time and effort for maintenance and high running cost.

In contrast, the manufacturing apparatus 10 of the present invention has the heat insulating member 40 (heat insulating means) which prevents the engagement members 24a of the LM guide 24 and the nut portion 32b of the ball screw 32 from being heated by the radiation heat from the heating/evaporating unit 16.

Accordingly, it is possible to prevent occurrence of a problem such as grease outflow due to heating of the catching members 24b and the nut portion 32b. As a result, a consistent operation can be performed for a long period of time, and the time and effort for maintenance and the running cost can be substantially reduced.

There are no particular limitations regarding the heat insulating member 40; various types of heat insulating member can be used as long as they block out the radiation heat from the heating/evaporating unit 16 and can prevent the catching members 24b, the nub portion 32b and further the base 36 from being heated. Examples of the heat insulating member include a stainless-steel plate, a steel plate, an aluminum plate, and a molybdenum plate. The method of fixing the member may be appropriately determined based on the type of the heat insulating member 40 used.

Further, means for cooling the heat insulating member 40 may be provided as needed. Examples of the cooling means include one causing cold water to flow through a pipe in contact with the heat insulating member 40 and one causing water to flow through a hole bored in a plate member (heat insulating member 40).

As described above, in the illustrated preferred embodiment, the heat insulating member 40 has an area larger than that of the base 36, and is arranged so as to cover the entire lower surface of the base 36 to which the catching members 24b of the LM guide 24 and the nut portion 32b of the ball screw 32 are fixed. However, the present invention is not restricted to this arrangement. For example, it is also possible to cover only the regions corresponding to the catching members 24b of the LM guide 24 and/or the region corresponding to the nut portion 32b of the ball screw 32 with the heat insulating member to protect them from the heating/evaporating unit 16.

However, to more suitably prevent the catching members 24b and the nut portion 32b from being heated, it is desirable, as in the illustrated embodiment, to cover the members that may conduct heat to the catching members 24b and the nut portion 32b with the heat insulating member 40 as widely as possible to protect them from the heating/evaporating unit 16.

In the lower portion of the vacuum chamber 12, there is arranged the heating/evaporating unit 16.

The heating/evaporating unit 16 is the unit for evaporating cesium bromide and europium bromide constituting the film forming materials by resistance heating.

As stated above, in a preferred embodiment of the manufacturing apparatus 10, there is conducted a two-source vacuum evaporation in which cesium bromide constituting the phosphor component and europium bromide constituting the activator component are heated and evaporated independently of each other. Thus, in the heating/evaporating unit 16, there are arranged resistance heating crucibles 50 serving as the evaporation sources for cesium bromide (for phosphor) and resistance heating crucibles 52 serving as the evaporation sources for europium bromide (for activator).

As in the case of the crucible used as the resistance heating evaporation source in ordinary vacuum evaporation, the crucibles 50 and 52 are formed of a high-melting-point metal such as tantalum (Ta), molybdenum (Mo), or tungsten (W), and generate heat on their own by being energized by an electrode (not shown), thereby heating/melting the film forming materials in the crucibles and evaporating the film forming materials.

In the present invention, there are no particular limitations regarding the power source for resistance heating (heating control means); it is possible to adopt various systems for use in resistance heating devices, such as a thyristor system, a DC system, or a thermocouple feedback system. Further, there are no particular limitations regarding the output when effecting resistance heating; it may be appropriately set according to the film forming materials used, the resistance value of the crucible forming material, the amount of heat generated, etc.

The ratio of activator to phosphor in a stimulable phosphor for example in terms of the molar concentration is approximately 0.0005/1 to 0.01/1, which means that most of the phosphor layer consists of phosphor.

Thus, in the illustrated embodiment, the crucible 50 for cesium bromide (for phosphor) whose evaporation amount is large is a large cylindrical (drum-shaped) crucible. The crucible 50 has in the side surface of the cylinder a slit-like opening extending in the axial direction of the cylinder, and in this opening, there is provided as the vapor discharge port, a quadrangular prism-shaped chimney 50a formed as a slit of the same shape as the opening and equipped with upper and lower opening surfaces.

In contrast, the crucible 52 for europium bromide (for activator) whose evaporation amount is small is a small crucible made up of an ordinary boat-shaped crucible whose upper surface is closed by a cover having a vapor discharge port. As in the case of the crucible 50, this cover has a chimney 52a corresponding to the slit-like opening as a vapor discharge port. The slit (opening) of the chimney 52a extends in the longitudinal direction of the crucible 52.

By using crucibles having such slit-like chimneys, it is possible to prevent the film forming materials from inadvertently getting out of the crucibles to adhere to the periphery thereof and the substrate S to thereby contaminate them, when bumping occurs due to local heating or abnormal heating in the crucibles. As stated above, in the case of medium vacuum evaporation, it is necessary for the substrate S and the evaporation sources to be close to each other, so that the above arrangement proves effective.

Here, in the manufacturing apparatus 10, the crucibles 50 and 52 are arranged in a direction perpendicular to the conveying direction. The crucibles are insulated from each other by, for example, spacing them apart from each other, or inserting insulating materials between them.

In this way, the substrate S is conveyed linearly, and evaporation sources such as crucibles are arranged in a direction perpendicular to the conveying direction (i.e., a direction perpendicular to the direction in which the substrate S is conveyed), whereby the entire surface of the substrate S is uniformly exposed to the vapor of the film forming materials, making it possible to form a phosphor layer suitably a film thickness distribution uniformity of ±3% or less.

As stated above, a high film thickness distribution uniformity of ±3% or less, more preferably ±2% or less is required of the phosphor layer of a phosphor sheet from which a radiation image is to be read by a line sensor.

Usually, as disclosed in, for example, JP 2003-344591 A mentioned above, when forming a phosphor layer through vacuum evaporation, film formation is effected while rotating the substrate to form a phosphor layer whose film thickness is wholly uniform. Here, when the substrate S is rotated, the velocity (linear velocity) of the substrate surface (film formation surface) differs in the radial direction.

Thus, for example, even when the evaporation sources are linearly arranged in the radial direction so that they may uniformly face the entire surface of the rotating substrate, the time period during which the substrate faces the evaporation sources differs in the radial direction due to the difference in the linear velocity of the substrate surface. Due to this difference, there arises a difference in the exposure amount of vapor to which the surface of the substrate S is exposed, depending upon the position in the rotating radial direction, resulting in a difference in film thickness. That is, in the case of medium vacuum evaporation in which the substrate is rotated, in order to expose the entire-surface of the substrate to vapor uniformly, some contrivance is required in terms of the arrangement of the evaporation sources in the heating/evaporating unit, and in order to realize the high film thickness distribution uniformity of ±3% or less, the position setting for the evaporation sources is very difficult to perform.

In particular, when there are used crucibles having slit-like chimneys suitable in avoiding problems caused by bumping as in the illustrated embodiment, the linear velocity of the substrate differs also in the portions above the slits, and the passage length above the slits differs depending upon the position on the substrate. Thus, to realize the high film thickness distribution uniformity, the position setting for the evaporation sources is still more difficult to perform.

Further, when phosphor layers made of various stimulable phosphors (in particular, a phosphor layer made of an alkali-halide-based stimulable phosphor, above all, a phosphor layer made of CsBr:Eu) are formed through vacuum evaporation with the manufacturing apparatus 10 of the present invention, it is desirable to once evacuate the system to a high degree of vacuum, and introduce an inert gas such as argon gas or nitrogen gas into the system which is kept evacuated, thereby forming a phosphor layer in a medium vacuum of 0.1 to 10 Pa, and more specifically 0.5 to 3 Pa. This makes it possible to form a phosphor layer having a satisfactory columnar crystal structure, and to manufacture a phosphor sheet superior in photostimulated luminescence characteristics and image sharpness.

The manufacturing apparatus 10 in the illustrated embodiment preferably performs phosphor layer formation in the medium vacuum. The manufacturing apparatus 10 has the gas introducing nozzle 18 to perform medium vacuum evaporation by resistance heating while introducing an inert gas.

However, in vacuum evaporation in such medium degree of vacuum, to enable the evaporated film forming materials to reliably reach the substrate S, it is necessary to substantially reduce the distance between the evaporation sources and the substrate S as compared with normal cases. Thus, the evaporated film forming materials are allowed to reach the substrate S before being sufficiently diffused, which makes it more difficult to secure the requisite film thickness uniformity.

In the case of evaporation by electron heating as disclosed in JP 2003-344591 A, the evaporation is effected in a high degree of vacuum, so that the substrate and the evaporation sources can be sufficiently spaced apart from each other. As a result, vapor of the film forming materials can be sufficiently diffused within the vacuum chamber (film formation system), whereby the entire surface of the substrate is exposed to the vapor. Thus, the difference in exposure amount due to the difference in the velocity of the substrate surface in the radial direction is canceled out, and the requisite uniformity in film thickness is easily secured; in particular, as disclosed in JP 2003-344591 A, it is possible to secure the highly uniform film thickness distribution by rotating the substrate at high speed.

However, as stated above, in the medium vacuum evaporation, it is necessary for the substrate S and the evaporation sources to be close to each other, so that the vapor from the evaporation sources is allowed to reach the substrate S before it has been sufficiently diffused. Thus, no matter how the high speed at which the substrate is rotated is, only a part of the substrate is exposed to the vapor. As a result, in the medium vacuum evaporation, due to the difference in the linear velocity of the substrate surface, the difference in vapor exposure amount in the radial direction further increases, and to realize the highly uniform film thickness distribution of ±3% or less, the position setting for the evaporation sources becomes still more difficult to perform.

In contrast, in the manufacturing apparatus 10 of the present invention, the formation of the phosphor layer is effected through vacuum evaporation while linearly conveying the substrate S, whereby it is possible to make the movement velocity of the surface of the substrate S (surface on which no film is formed) wholly uniform. Further, by arranging evaporation sources (crucibles) linearly in a direction perpendicular to the conveying direction (a direction perpendicular to the direction in which the substrate S is linearly conveyed), it is possible to expose the entire surface of the substrate S uniformly to the vapor of the forming materials owing to this very simple arrangement of the evaporation sources. As a result, it is possible to form a phosphor layer exhibiting the highly uniform film thickness distribution of ±3% or less.

Further, owing to this construction, it is possible to diffuse in a highly uniform manner the activator component in the stimulable phosphor layer in both the planar direction and thickness direction of the phosphor layer, whereby it is possible to obtain a phosphor sheet superior in photostimulated luminescence characteristics and uniformity in sensitivity, etc.

It is possible to secure the uniformity in film thickness distribution to some extent with a single evaporation source extending in the conveyance perpendicular direction. Xn this construction, however, when the size of the substrate S is increased, it is necessary to increase the size of the evaporation source accordingly, which may lead to unevenness in temperature and unevenness in evaporation amount in the conveyance perpendicular direction, resulting in nonuniform film thickness distribution.

Thus, to form in a consistent manner a phosphor layer whose film thickness distribution is as high as ±3% or less, it is necessary, as in the present invention, to arrange evaporation sources in the conveyance perpendicular direction. Further, regarding the evaporation sources for heating and evaporating the film forming materials in a large amount (i.e., the crucibles 50 for cesium bromide in the illustrated embodiment), it is desirable to individually control evaporation by using sensors as described below.

In the present invention, there are no particular limitations regarding the number of evaporation sources arranged in the conveyance perpendicular direction.

Basically, the larger the number of evaporation sources is, the more excellent the film thickness distribution uniformity becomes. On the other hand, an increase in the number of evaporation sources is disadvantageous from the viewpoint of cost, controllability, etc.; further, the number of gaps between the evaporation sources are also increased, which is also disadvantageous in terms of film formation rate, etc. Thus, the number of evaporation sources arranged in the conveyance perpendicular direction may be appropriately determined based on the size of substrate S, the desired film thickness of the phosphor layer, the requisite film thickness distribution uniformity, the apparatus cost, etc.

An examination conducted by the present inventors has shown that, when forming a phosphor layer on the substrate S of, for example, 450×450 mm through medium vacuum evaporation as described above, the phosphor layer formed can be superior in film thickness distribution uniformity through vacuum evaporation using, as in the illustrated case, two rows of crucibles each of which consists of six crucibles (that is, using 12 crucibles for both the phosphor and activator), with each crucible having a slit-like discharge port as described above.

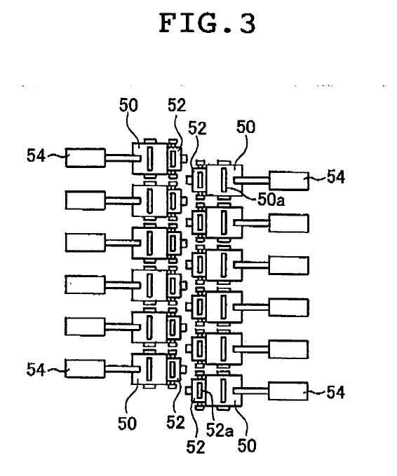

FIG. 3 is a schematic plan view of the heating/evaporating unit 16. In the embodiment as shown in FIG. 3, six crucibles 50 for cesium bromide are arranged, with the axial direction of the cylinders (drums) being in conformity with the conveyance perpendicular direction. In the illustrated embodiment, two rows of the crucibles 50 are provided.

The electrodes of the crucibles 50 are formed on the end surfaces of the cylinders, and the crucibles 50 are connected independently to the power source. As a preferred mode, there are provided for the respective crucibles 50, quartz oscillator sensors 54 (which are omitted in FIG. 1 to clarify the general construction of the apparatus) for measuring the evaporation amount of cesium bromide and, based on the measurement result, the amount of electricity supplied to the crucibles 50 is controlled. As a result, the evaporation amount of cesium bromide, which is evaporated in a large amount, is controlled for each crucible 50, making it possible to form a phosphor layer whose film thickness distribution is more highly uniform.

The control of the evaporation amount may be effected based on the measurement of the temperature of the crucibles by a temperature sensor. Further, in terms of the uniformity in film thickness distribution, it is desirable to perform evaporation amount control on each crucible 50 as in the illustrated embodiment, but it is also possible to perform evaporation amount control for each group of more than one crucible, for example, two crucibles connected together in series or in parallel in order to reduce the apparatus cost, etc.

Similarly, six crucibles 52 for europium bromide, which are boat-shaped crucibles, are arranged with the longitudinal direction being in conformity with the arrangement direction. In the case of the crucibles 52 also, electrodes are formed at both ends in the arrangement direction of the crucibles, with the crucibles being individually connected to independent power sources.

As in the case of the crucibles 50, the crucibles 52 are also arranged in two rows each of which consists of six crucibles.

In each of the rows of the crucibles 50 and 52, it is desirable for the adjacent crucibles 50 and 52 to be arranged as close to each other as possible in the arrangement direction based on the construction of the apparatus and the crucibles. Further, it is desirable for each crucible row to have a sufficient length for the size of the substrate S in the direction in which the crucibles are arranged.

Owing to the construction described above, the evaporation amount of the film forming materials in the conveyance perpendicular direction is made uniform, whereby a phosphor layer of more highly uniform film thickness distribution can be formed.

Further, in the illustrated embodiment, there is adopted as a preferred mode, an arrangement in which one crucible 50 and one crucible 52 constituting a pair are arranged side by side in the conveying direction. In other words, there is adopted as a preferred mode, an arrangement in which one evaporation source for cesium bromide which is a phosphor film forming material, and one evaporation source for europium bromide which is an activator film forming material, constitute a pair, and are arranged side by side in the conveying direction. Further, as a more preferred mode, the crucibles 50 and 52 are arranged as close to each other as possible based on the construction of the apparatus and the two crucibles.

Owing to the construction described above, the vapor of europium bromide is sufficiently diffused into the vapor of cesium bromide constituting the base material to uniformly diffuse the europium (activator), which is a minute-amount component, into the phosphor layer, thereby making it possible to form a phosphor layer exhibiting excellent photostimulated luminescence characteristics, etc.

The number of such rows of crucibles for the film forming materials in the conveyance perpendicular direction (hereinafter referred to as the crucible rows) may be one, or two as in the illustrated embodiment, or three or more. Further, the number of crucible rows may differ among the film forming materials.

Here, in the case in which more than one crucible row is used for one film forming material, it is desirable for the crucible rows to be arranged such that, as seen in the conveying direction, the discharge ports (slit-like chimneys) provided in the crucibles of the respective crucible rows for discharging vapor of the film forming material form no gap in the arrangement direction. Further, in this case, it is more desirable to arrange the crucible rows such that the discharge ports for film forming material vapor of different crucible rows do not overlap each other in the conveying direction. In other words, it is desirable to arrange the crucible rows such that, when seen in the conveying direction, the discharge ports for film forming material vapor in the crucible rows are arranged alternately. In the illustrated embodiment, two crucible rows for one film forming material are arranged such that, when seen in the conveying direction, the vapor discharge ports of one crucible row are situated at the electrode positions of the other crucible row.

Owing to the construction described above, the evaporation amount of the film forming material in the arrangement direction is made uniform, whereby a phosphor layer of more highly uniform film thickness distribution can be formed.

Further, for the same reason, it is desirable to use crucibles having slit-like vapor discharge ports such as the chimneys 50a and 52a in the illustrated embodiment, and to arrange them such that the longitudinal direction of the vapor discharge ports is in conformity with the arrangement direction (the direction perpendicular to the conveying direction).

Further, in the case in which more than one crucible row is provided, it is desirable to position the rows of the crucibles 50 for cesium bromide (the phosphor film forming material) whose evaporation amount is large on the outer sides in the conveying direction.

The construction described above makes it possible to arrange the evaporation amount sensors for cesium bromide whose evaporation amount is large, in the open spaces on the outer sides of the crucible rows in the conveying direction. As a result, it is possible to improve the degree of freedom in the selection of the evaporation amount sensors (or temperature sensors), the degree of freedom in the arrangement, and the degree of freedom in the design of the manufacturing apparatus 10.

Further, although not shown, in the heating/evaporating unit 16 of the manufacturing apparatus 10, there is arranged a quadrangular prism-shaped heat insulating plate which surrounds all the crucibles from the four horizontal sides and which is provided at a higher position than the uppermost portions of the crucibles, and there is arranged a shutter for blocking out the film forming material vapor so that the upper open surface of this heat insulating plate can be closed or opened as desired.

In the following, the operation for forming a phosphor layer on the substrate S by the manufacturing apparatus 10 (the manufacture of a phosphor sheet) will be described.

First, the vacuum chamber 12 is opened, and the substrate S is retained by the retaining mechanism 38b of the retaining means 26; further, all the crucibles 50 and 52 are filled with cesium bromide and europium bromide to predetermined amounts, respectively. Thereafter, the shutter is closed, and further, the vacuum chamber 12 is closed.

Subsequently, a vacuum evacuating means is driven to evacuate the vacuum chamber 12. When the internal pressure of the vacuum chamber 12 reaches, for example, 8×10⁻⁴ Pa, argon gas is introduced through the gas introducing nozzle 18 into the vacuum chamber 12, which is continuously evacuated to thereby adjust the internal pressure of the vacuum chamber 12 to, for example, 1 Pa. Subsequently, the power source for resistance heating is driven to energize all the crucibles 50 and 52, thereby heating the film forming materials.

When a predetermined period of time has elapsed after the s art of the heating, the shutter is opened, and then the motor 34 is driven to start the linear conveyance of the substrate S at a predetermined speed, thus starting the formation of a phosphor layer on the surface of the substrate S.

When a predetermined number of to-and-fro movements for linear conveyance set in advance based on the thickness of the phosphor layer to be formed or the like have been completed, the linear conveyance of the substrate S is stopped, the shutter is closed, and the power source for resistance heating is turned off. Thereafter, the amount of argon gas introduced through the gas introducing nozzle 18 is increased, and the internal pressure of the vacuum chamber 12 is adjusted to the atmospheric pressure. When the interior of the vacuum chamber 12 has reached the atmospheric pressure, the vacuum chamber is opened, and the substrate S on which a phosphor layer formed, that is, the phosphor sheet manufactured is taken out of the chamber.

This phosphor sheet is obtained by forming on the substrate a phosphor layer through medium vacuum evaporation by resistance heating while linearly conveying the substrate, so that the phosphor sheet is a high-quality one that has the phosphor layer which exhibits highly uniform film thickness distribution and excellent crystallinity, and is superior in photostimulated luminescence characteristics and image sharpness.

While crucibles for resistance heating are used as the evaporation sources in the above embodiment, the first aspect of the present invention is not restricted thereto; various types of evaporation sources can be utilized as long as they can be arranged in the conveyance perpendicular direction.

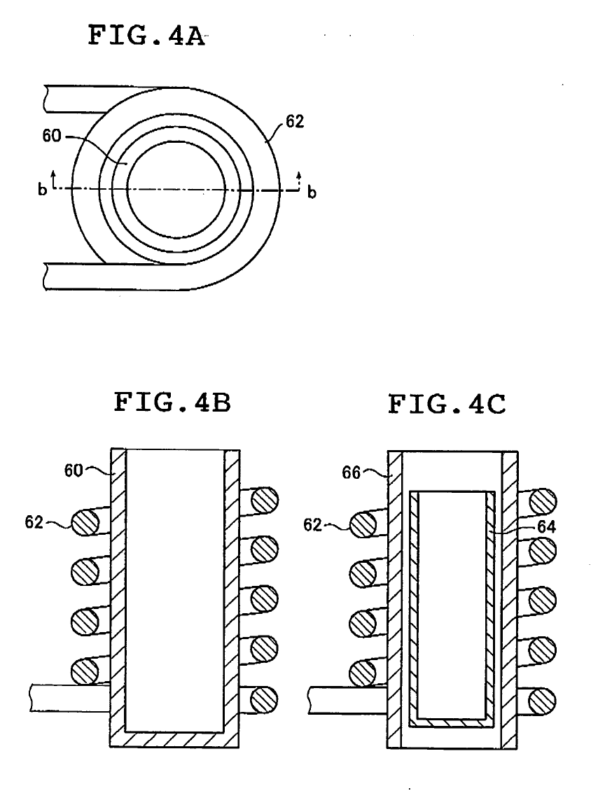

FIG. 4A is a plan view showing another example of the evaporation source and FIG. 4B is a sectional view of the evaporation source shown in FIG. 4A taken along the line b-b. For example, as shown in FIGS. 4A and 4B, evaporation sources relying on induction heating each of which includes a crucible 60 formed of a material with sufficient magnetic permeability like carbon, a heating coil 62 loosely wound around the crucible 60 and a high frequency power source (not shown) supplying high frequency power to the heating coil 62, may be arranged in the conveyance perpendicular direction. Alternatively, as shown in FIG. 4C, evaporation sources each of which includes a cylindrical heating member 66 formed of a material with sufficient magnetic permeability, a crucible 64 inserted into the heating member 66 and the heating coil 62 and in which the heating member 66 is heated by induction heating using the heating coil 62 to thereby heat the crucible 64 by radiation heat may be arranged in the conveyance perpendicular direction.

In this case, it is desirable to provide one high frequency power source for each crucible to perform evaporation control individually. Alternatively, as in the case of the crucibles 50, it is possible to connect the heating coils 62 in series or in parallel and to provide one high frequency power source for more than one crucible so that evaporation control can be performed for more than one crucible.

Further, more than one crucible may be arranged in the conveyance perpendicular direction to allow the film forming materials to be evaporated by electron beams from an electron gun.

In this case, the film forming materials in the respective crucibles may be heated by scanning with electron beams from a single electron gun using magnetic force or the like. Alternatively, if possible, each crucible may be provided with an electron gun.

While the phosphor sheet manufacturing apparatus of the present invention has been described above in detail, the present invention is by no means limited to the foregoing embodiment and various improvements and modifications may course be made without departing from the scope and spirit of the invention.

For example, while in the illustrated embodiment, there are provided crucible rows in which only the crucibles 50 for cesium bromide (for the phosphor component) are arranged and crucible rows in which only the crucibles 52 for europium bromide (for the activator component) are arranged, this should not be construed restrictively. For example, it is also possible to arrange the crucibles 50 for cesium bromide and the crucibles 52 for europium bromide 52 alternately, thus forming a crucible row in the conveyance perpendicular direction.

### EXAMPLE

In the following, the present invention will be described in more detail with reference to a specific example thereof.

First, the vacuum chamber 12 was opened, and an aluminum substrate S of 450×450 mm and with a thickness of 10 mm was secured to the retaining mechanism 38b of the retaining means 26; further, all the crucibles 50 were filled with cesium bromide (CsBr) and all the crucibles 52 were filled with europium bromide (EuBrₓ, where x is approximately 2) to predetermined amounts. Then, the shutter was closed, and further, the vacuum chamber 12 was closed.

After the vacuum chamber 12 was closed, the vacuum evacuating means was driven to start the evacuation of the vacuum chamber 12. When the internal pressure of the vacuum chamber 12 reaches 8×10⁻⁴ Pa, argon gas was introduced into the vacuum chamber 12 through the gas introducing nozzle 18 while continuing the evacuation to thereby adjust the internal pressure of the vacuum chamber 12 to 1 Pa. Further, the power source for resistance heating was driven to energize all the crucibles 50 and 52 to thereby heat the film forming materials.

The shutter was opened 40 minutes after the start of the heating and then the motor 34 was driven to start the linear conveyance of the substrate S, thereby starting the formation of a phosphor layer.

The speed at which the substrate S was conveyed was 200 mm/sec, and the substrate S was moved in a to-and-fro manner to form the phosphor layer. That is, the substrate S was conveyed to an end of the LM guide 24 and then conveyed in the opposite direction.

Further, during the film formation, the output of the resistance heating power source to each crucible was set such that the molar concentration ratio of Eu/Cs was 0.003:1. This setting was effected based on previously conducted film forming experiments. The amount of electricity supplied to the crucibles 50 for cesium bromide was adjusted such that the evaporation amounts of all the crucibles 50 are equalized, using the above-mentioned setting as a reference and based on the evaporation amount measurement results obtained by the quartz oscillator sensors 54.

After the start of the film formation, when the to-and-fro movement of the substrate S was repeated 1000 times, the linear conveyance of the substrate S was finished, and the shutter was closed, futher, the power source for resistance heating was turned off to stop the electricity supply to the crucibles. Thereafter, the amount of argon gas introduced through the gas introducing nozzle 18 was increased to adjust the interior of the vacuum chamber 12 to the atmospheric pressure. Then, the vacuum chamber 12 was opened, and the substrate S on which a phosphor layer whose thickness is approximately 600 μm had been formed, that is, the phosphor sheet prepared was taken out of the vacuum chamber 12. The number of times the substrate is moved in a to-and-fro manner was to be effected was determined based on previously conducted experiments such that the film thickness of the phosphor layer would be 600 μm.

The film thickness distribution of the phosphor layer of the prepared phosphor sheet was measured using a stylus instrument for measuring film thickness (SURFCOM 1400D-LCD manufactured by Tokyo Seimitsu, Co., Ltd.).

The resultant film thickness distribution was ±2%.

The above result clearly shows the advantage of the present invention.

1. A phosphor sheet manufacturing apparatus for forming a stimulable phosphor layer on a surface of a sheet-like substrate through vacuum evaporation, comprising:
a vacuum chamber in which said vacuum evaporation is performed;
vacuum evacuating means for evacuating said vacuum chamber;
substrate conveying means for conveying said substrate along a linear conveyance route in said vacuum chamber; and
evaporation sources accommodated in said vacuum chamber, arranged below said linear conveyance route along which said substrate is conveyed by said substrate conveying means, and arrayed in a first direction perpendicular to a second direction in which said substrate is conveyed.

2. The phosphor sheet manufacturing apparatus according to claim 1, wherein said stimulable phosphor layer is formed while said substrate is conveyed in a to-and-fro manner by said substrate conveying means.

3. The phosphor sheet manufacturing apparatus according to claim 1,
wherein said vacuum evaporation is multi-source vacuum evaporation through which said stimulable phosphor layer is formed using film forming materials, and
wherein evaporation sources for each film forming material in said film forming materials are arranged in said first direction perpendicular to said second direction to make a row of evaporation sources, and rows of evaporation sources for respective film forming materials are arrayed in said second direction in which said substrate is conveyed.

4. The phosphor sheet manufacturing apparatus according to claim 3, wherein evaporation sources for said one film forming material and their corresponding evaporation sources for another film forming material are arranged side by side in said second direction in which said substrate is conveyed.

5. The phosphor sheet manufacturing apparatus according to claim 4,
wherein said film forming materials include a first film forming material constituting a phosphor component and a second film forming material constituting an activator component, and
wherein first evaporation sources for said first film forming material are paired with second evaporation sources for said second film forming material and pairs of said first and second evaporation sources are arranged side by side in said second direction in which said substrate is conveyed.

6. The phosphor sheet manufacturing apparatus according to claim 1, wherein said evaporation sources have slit-like vapor discharge ports, and wherein said evaporation sources are arranged such that a longitudinal direction of each of said slit-like vapor discharge ports is matched with said first direction perpendicular to said second direction.

7. The phosphor sheet manufacturing apparatus according to claim 1, wherein at least one of said film forming materials is capable of controlling its evaporation for each evaporation source.

8. The phosphor sheet manufacturing apparatus according to claim 1, wherein evaporation sources for each of said film forming materials are provided in rows and said evaporation sources in the rows are arranged such that, when seen in said second direction in which said substrate is conveyed, vapor discharge ports of adjacent rows are arranged alternately.

9. The phosphor sheet manufacturing apparatus according to claim 3, wherein a row of evaporation sources for one film forming material whose evaporation amount is largest in said film forming materials is arranged outermost in said second direction in which said substrate is conveyed.

10. The phosphor sheet manufacturing apparatus according to claim 1, wherein said evaporation sources heat film forming materials by resistance heating or induction heating.

11. The phosphor sheet manufacturing apparatus according to claim 10, further comprising:
gas introducing means which introduces an inert gas into said vacuum chamber during film formation to adjust a degree of vacuum in said vacuum chamber.

12. The phosphor sheet manufacturing apparatus according to claim 11, wherein said stimulable phosphor layer is formed by adjusting an internal pressure of said vacuum chamber to from 0.1 to 10 Pa through introduction of said inert gas by said gas introducing means.

13. The phosphor sheet manufacturing apparatus according to claim 12, wherein said substrate conveying means comprises:
guide means extending in said second direction in which said substrate is conveyed;
substrate retaining means having engagement portions which are engaged with said guide means;
driving means for moving said substrate retaining means in said second direction in which said substrate is conveyed; and
a heat insulating mechanism for preventing said engagement portions from being heated by radiation heat from said evaporation sources.

14. The phosphor sheet manufacturing apparatus according to claim 1, wherein said stimulable phosphor layer is made of a stimulable phosphor that is expressed by a general formula: “CsBr:Eu”.

15. A phosphor sheet manufacturing apparatus for forming a stimulable phosphor layer on a surface of a sheet-like substrate through vacuum evaporation, comprising:
a vacuum chamber in which said vacuum evaporation is performed;
vacuum evacuating means for evacuating said vacuum chamber;
resistance heating means for heating film forming materials of said stimulable phosphor layer by resistance heating, said resistance heating means being accommodated in said vacuum chamber;
substrate conveying means for conveying said substrate along a linear conveyance route above said resistance heating means in said vacuum chamber; and
gas introducing means for introducing an inert gas into said vacuum chamber during film formation of said stimulable phosphor layer to adjust a degree of vacuum in said vacuum chamber.

16. The phosphor sheet manufacturing apparatus according to claim 15, wherein said substrate conveying means comprises:
guide means extending in a direction in which said substrate is conveyed along said linear conveyance route;
substrate retaining means having engagement portions which are engaged with said guide means;
driving means for moving said substrate retaining means in said direction in which said substrate is conveyed; and
a heat insulating mechanism for preventing said engagement portions from being heated by radiation heat from said resistance heating means.

17. The phosphor sheet manufacturing apparatus according to claim 15, wherein said stimulable phosphor layer is formed by adjusting an internal pressure of said vacuum chamber to from 0.1 to 10 Pa through introduction of said inert gas by said gas introducing means.

18. The phosphor sheet manufacturing apparatus according to claim 15, wherein said stimulable phosphor layer is formed while said substrate conveying means conveys said substrate in a to-and-fro manner along said linear conveyance route.

19. The phosphor sheet manufacturing apparatus according to claim 15, wherein said stimulable phosphor layer is made of a stimulable phosphor that is expressed by a general formula: “CsBr:Eu”.
